(19) United States
(12) Patent Application Publication
(10) Pub. No.: US 2026/0221946 A1
(43) Pub. Date: Jul. 30, 2026

(54) TEMPERATURE-COMPENSATED DIRECTIVITY CONTROL IN POWER AMPLIFIER MODULES

(71) Applicant: pSemi Corporation, San Diego, CA (US)

(72) Inventors: Vinay Kumar PEDDIREDDY, ARLINGTON HEIGHTS, IL (US); David KOVAC, ARLINGTON HEIGHTS, IL (US)

(21) Appl. No.: 19/039,624

(22) Filed: Jan. 28, 2025

(51) Int. Cl. H03F 1/30; H03F 3/24

(52) U.S. Cl. CPC H03F 1/303; H03F 3/245; H03F 2200/387; H03F 2200/451

(57) ABSTRACT

Systems and methods for temperature-compensated directivity control in a power amplifier module that includes a directional coupler coupled to a power amplifier is presented. A termination resistance having a temperature profile that varies with temperature is coupled to an isolation port of the directional coupler. The temperature profile is predetermined and based on measured and/or simulated data representing variation of directivity of the power amplifier module with temperature. The temperature profile is further based on measured and/or simulated correlation data between directivity and termination resistance. According to one aspect, the termination resistance is provided by one or more FETs whose gate voltages are controlled via a feedback loop that includes a bandgap voltage reference and a temperature-dependent current source. According to another aspect, the termination resistance is provided by one or more composite resistors, each composite resistor including at least two resistors with different temperature coefficients.

### TECHNICAL FIELD

The present application is related to electronic radio frequency (RF) circuits, and more particularly to temperature compensation of directivity in power amplifier modules.

### BACKGROUND

Power amplifiers (PAs) are widely used in radio frequency (RF) communication systems to increase the power of transmitted signals. In many applications, these power amplifiers are integrated into (power amplifier) modules that also contain directional couplers used to monitor the output power of the amplifiers. Monitoring/measuring/detecting of the output power is provided via a portion of the power output by the amplifier that is coupled through the directional coupler. Such coupled power can be used to monitor/control/adjust/correct one or more performances of the amplifier module, including, for example, a power radiated through an antenna port and/or an impedance mismatch at the antenna port.

Undesired signal/power leaks through ports of the directional coupler may lead to a coupled power that is not representative of the output power of the amplifier. This in turn may lead to errors in the measured coupled power with rippling effects in the ability to accurately monitor/control/adjust/correct performances of the amplifier module. One cause of such undesired signal/power leaks may be contributed to a variation (e.g., degradation, drop) of the directivity of the amplifier module with respect to temperature.

It follows that teachings according to the present disclosure describe systems and methods to maintain the directivity of power amplifier modules across temperature variations, thereby ensuring reliable and accurate operation of the power amplifier modules.

### SUMMARY

The present disclosure provides systems and methods for maintaining directivity in power amplifier modules across temperature variations by implementing a (directional) coupler termination resistance that varies with temperature according to a predetermined temperature response (e.g., profile, coefficient). The predetermined temperature response can be based on one or more slopes representing resistance variation over respective one or more temperature ranges.

In a first implementation, the termination resistance is realized via one or more of field-effect transistors (FETs) operating in the triode region. Gate voltages of the FETs are dynamically controlled by a feedback loop to effectively vary the termination resistance with temperature. This implementation includes an operational amplifier with temperature-stable reference voltage derived from a bandgap volage reference, along with a temperature-dependent current source to achieve the predetermined temperature response. The temperature-dependent current source may include a temperature profile according to any one or more of a proportional to absolute temperature (PTAT) profile, and/or a complementary to absolute temperature (CTAT) profile. The temperature profile may further include a zero-proportionality to absolute temperature (ZTAT) profile. The temperature profile may be based on a combination of a PTAT, a CTAT, and/or a ZTAT profile.

In a second implementation, the termination resistance is realized via a composite resistor that includes a combination of resistors with different inherent/characteristic temperature coefficients. By properly ratioing resistors with different (e.g., positive and/or negative) temperature coefficients (such as N-type and P-type polysilicon resistors), a desired overall temperature response of the composite resistor can be achieved. In a related implementation, several such composite resistors are combined with switches to provide selectivity of resistance value and temperature response.

Both implementations compensate for changes in directivity of the power amplifier module across temperature by adjusting the termination resistance to the directional coupler, thereby preserving measurement accuracy of the power coupled through the directional coupler, both in a forward power detection mode and a reverse (e.g., reflected) power detection mode.

Further aspects of the disclosure are provided in the description, drawings and claims of the present application.

### BRIEF DESCRIPTION OF THE DRAWINGS

The accompanying drawings, which are incorporated into and constitute a part of this specification, illustrate one or more embodiments of the present disclosure and, together with the description of example embodiments, serve to explain the principles and implementations of the disclosure.

FIG. 1A shows a block diagram of a power amplifier module incorporating temperature-compensated directivity control according to embodiments of the present disclosure.

FIG. 1B shows an exemplary block diagram of a more complex power amplifier module common to RF front end cellular applications.

FIG. 2A shows a desired signal path and an undesired signal path through the directional coupler of FIG. 1A configured for forward power detection mode.

FIG. 2B shows a desired signal path and an undesired signal path through the directional coupler of FIG. 1A configured for reverse power detection mode.

FIG. 3 shows graphs representative of measured directivity versus temperature variation and frequency band.

FIG. 4 shows graphs representative of relationships between directivity and coupled power error for forward and reverse power detection modes.

FIG. 5A and FIG. 5B show graphs representative of sensitivity of directivity to varying coupler termination resistance over temperature for forward and reverse power detection modes.

FIG. 6A shows a coupler termination resistance with an exemplary temperature response according to the present disclosure.

FIG. 6B shows various exemplary temperature responses of the coupler termination resistance of FIG. 6A.

FIG. 7A shows a simplified circuit implementation of the coupler termination resistance of FIG. 6A including a basic resistance unit element provided by a FET.

FIG. 7B shows a variation of the circuit implementation of FIG. 7A.

FIG. 8A shows a simplified circuit implementation of the coupler termination resistance of FIG. 6A including a basic resistance unit element provided by a composite resistor.

FIG. 8B shows two exemplary realizations of the basic resistance unit element.

FIG. 8C shows a simplified circuit implementation of the coupler termination resistance of FIG. 6A including a basic resistance unit element provided by a composite resistor.

FIG. 8D shows a simplified block diagram of a coupler termination resistance with temperature-based switch control.

FIG. 9 shows various process steps of a method according to the present disclosure.

Like reference numbers and designations in the various drawings indicate like elements.

### DETAILED DESCRIPTION

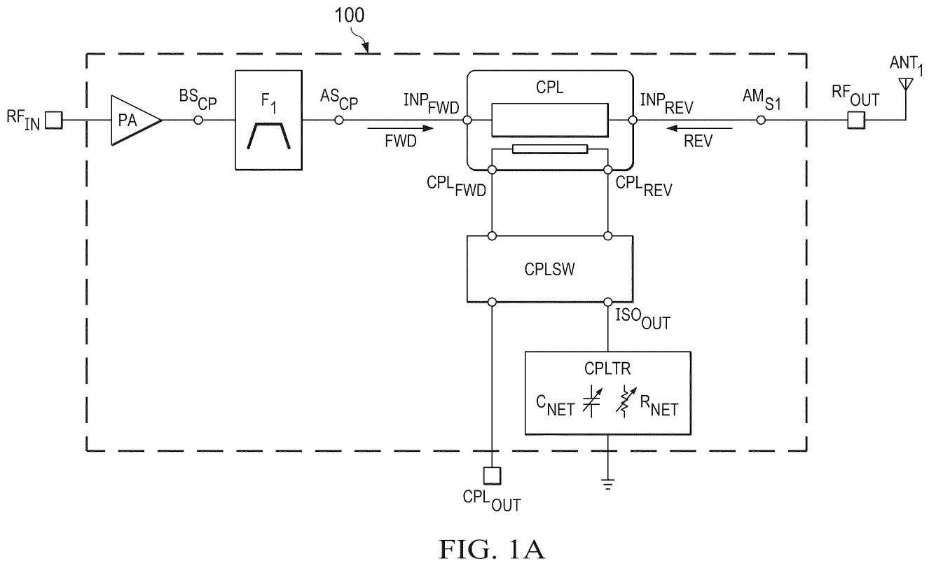

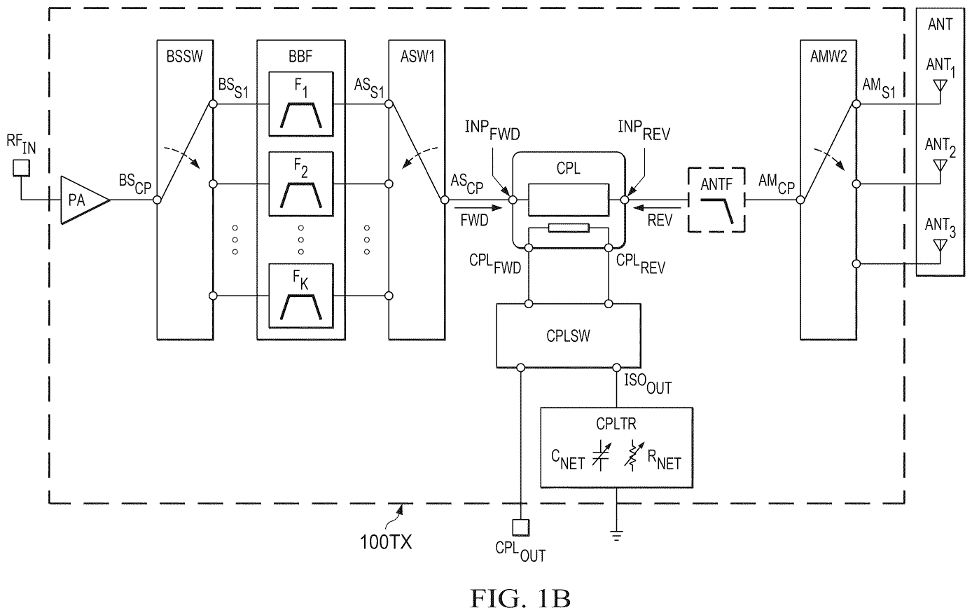

FIG. 1A shows a block diagram of a power amplifier module (100) incorporating temperature-compensated directivity control according to embodiments of the present disclosure. Elements of the power amplifier module (100) include a power amplifier, PA, a directional coupler, CPL, and a temperature-controlled termination circuit, CPLTR. The power amplifier module (100) receives an RF input signal at input port, RF_{IN}, and provides an amplified output signal at an output port, RF_{OUT}.

The directional coupler, CPL, includes a first main-line port, INP_{FWD}, coupled at a node, AS_{CP}, to an output of the power amplifier, PA, and a second main-line port, INP_{REV}, coupled at a node, AM_{S1}, to the output port, RF_{OUT}. The directional coupler, CPL, further includes ports (CPL_{FWD}, CPL_{REV}) that are selectively coupled, via a switching circuit, CPLSW, to either an isolation port, ISO_{OUT} or a coupled power port, CPL_{OUT}.

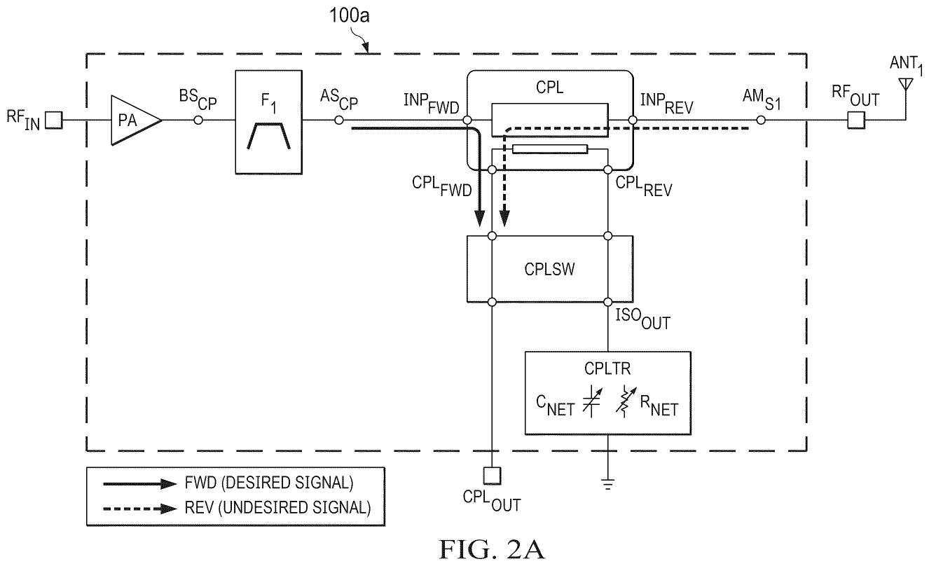

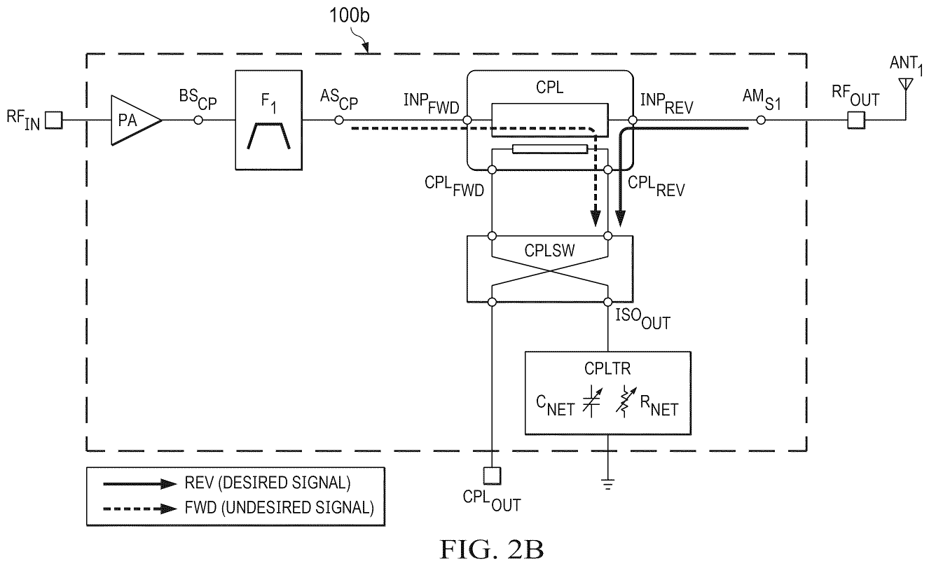

The switching circuit, CPLSW, allows operation of the directional coupler, CPL, in both a forward (FWD) power detection mode and a reverse (REV, e.g., reflected) power detection mode. In the forward power detection mode (e.g., FIG. 2A later described), the switching circuit, CPLSW, couples (e.g., connects) the CPL_{FWD} port and the CPL_{REV} port of the directional coupler, CPL, respectively to the CPL_{OUT} port and the ISO_{OUT} port. On the other hand, in the reverse power detection mode (e.g., FIG. 2B later described), the switching circuit, CPLSW, couples (e.g., connects) the CPL_{FWD} port and the CPL_{REV} port of the directional coupler, CPL, respectively to the ISO_{OUT} port and the CPL_{OUT} port.

When configured for operation in the forward power detection mode, the directional coupler, CPL, couples (e.g., via a coupler coupling factor) a portion of an RF signal that travels in the FWD direction through ports (INP_{FWD}, INP_{REV}) to the CPL_{FWD} port, and therefore to the CPL_{OUT} port via the switching circuit, CPLSW. On the other hand, when configured for operation in the reverse power detection mode, the directional coupler, CPL, couples a portion of an RF signal that travels in the REV direction through ports (INP_{FWD}, INP_{REV}) to the CPL_{REV} port, and therefore to the CPL_{OUT} port via the switching circuit, CPLSW (e.g., FIG. 2B later described).

The combination of the directional coupler, CPL, with the switching circuit, CPLSW, may be considered a four-port configurable directional coupler that includes: the first main-line port, INP_{FWD}, which may be considered as a forward input port, coupled to the output of the power amplifier, PA; the second main-line port, INP_{REV}, which may be considered as a reverse input port, coupled to the output port, RF_{OUT}; an isolated port, ISO_{OUT}, connected to the temperature-controlled termination circuit, CPLTR; and the coupled port, CPL_{OUT}, for providing a coupled power representing a power of the RF signal travelling through the first and second main-line ports in either the forward or reverse direction.

With continued reference to FIG. 1A, the output port, RF_{OUT}, of the power amplifier module (100) may be coupled to a load, such as, for example, an antenna, ANT₁. The Antenna, ANT₁, may be used for transmission of the amplified RF signal at the output port, RF_{OUT}. The amplified RF signal may be subjected to filtering via a (band) filter, F₁, coupled between nodes BS_{CP} and AS_{CP}. The filter F₁ may be used for tuning of the amplified RF signal prior to transmission via the antenna, ANT₁. Such tuning may correspond to a frequency band of operation supported by the power amplifier module (100). It is noted that operation of the power amplifier module (100) may be in view of a VSWR (voltage standing wave ratio) load performance at the antenna (e.g., ANT₁) which determines an expected ratio between transmitted and reflected RF power at the load, or in other words, between power of an RF signal travelling in the FWD direction and an RF signal travelling in the REV direction.

The power amplifier module (100) may be included in, or be part of, an RF front-end module, such as for example, an RF transmit (TX) module. FIG. 1B shows an exemplary block diagram of an RF front-end module (100TX) incorporating the power amplifier module (100) of FIG. 1A. The RF front-end module (100TX) can be a multi-band RF front-end module that supports a plurality of frequency bands of operation. Multi-band functionality may be provided via inclusion of one or more switches (e.g., BSSW, ASW1, AMW2) and various filters (e.g., BBF, ANTF) for provision of a plurality of band-specific (switchable) RF transmit paths. Each such RF transmit path amplifying an RF signal at the input port, RF_{IN}, via the power amplifier, PA, and providing a corresponding coupled power at the CPL_{OUT} port via the combination of the directional coupler, CPL, and switching circuit, CPLSW.

With continued reference to FIG. 1B, switches BSSW (e.g., band switch) and ASW1 (e.g., antenna switch) in combination with a bank of (band) filters ((F₁, F₂, . . . , F_{K}) may selectively configure operation of the RF front-end module (100TX) according to a band-specific RF transmit path provided between nodes BS_{CP} and AS_{CP}, with node BS_{CP} coupled (e.g., connected) to the output of the power amplifier, PA, and node AS_{CP} coupled (e.g., connected) to the first main-line port, INP_{FWD}, of the directional coupler, CPL. Furthermore, a switch, AMW2, may selectively couple, e.g., via an optional antenna filter, ANTF, the second main-line port, INP_{REV}, of the directional coupler, CPL, to an antenna of one or more antennae (e.g., ANT₁, ANT₂, ANT₃). For example, considering the configuration of the switches (BSSW, ASW1, AMW2) shown in FIG. 1B, the selected band-specific RF transmit path passes through nodes BS_{CP}, BS_{S1}, AS_{S1}, AS_{CP}, AM_{CP}, and AM_{S1}, to include the filter F1 for tuning of the amplified RF signal and the antenna ANT₁ for transmission. In other words, the block diagram of the power amplifier module (100) of FIG. 1A can be considered as one band-specific configuration (e.g., including one transmit path) of the multi-band RF front-end module (100TX, e.g., a multi-band RF transmit module) of FIG. 1B. In other words, teachings according to the present disclosure may equally apply to the RF front-end module (100TX) or any variation thereof that includes a power amplifier coupled to a directional coupler.

FIG. 2A shows a configuration (100a) of the power amplifier module (100) of FIG. 1A for operation according to the forward power detection mode. Accordingly, and as shown in FIG. 2A, the switching circuit, CPLSW, couples (e.g., connects) the CPL_{FWD} port and the CPL_{REV} port of the directional coupler, CPL, respectively to the CPL_{OUT} port and the ISO_{OUT} port. In the forward power detection mode, the coupled power at the CPL_{OUT} port is expected to be representative of a power of an RF signal (desired signal of FIG. 2A) travelling in the forward direction (FWD). However, presence of undesired RF signal leaks (undesired signal of FIG. 2A) travelling in the reverse direction (REV) that may couple to the CPL_{OUT} port may result in an erroneous coupled power that is not representative of the RF signal travelling in the forward direction (FWD).

On the other hand, FIG. 2B shows a configuration (100b) of the power amplifier module (100) of FIG. 1A for operation according to the reverse (e.g., reflected) power detection mode. Accordingly, and as shown in FIG. 2B, the switching circuit, CPLSW, couples (e.g., connects) the CPL_{FWD} port and the CPL_{REV} port of the directional coupler, CPL, respectively to the ISO_{OUT} port and the CPL_{OUT} port. In the reverse power detection mode, the coupled power at the CPL_{OUT} port is expected to be representative of a power of an RF signal (desired signal of FIG. 2B) travelling in the reverse direction (REV). However, presence of undesired RF signal leaks (undesired signal of FIG. 2B) travelling in the forward direction (FWD) that may couple to the CPL_{OUT} port may result in an erroneous coupled power that is not representative of the RF signal travelling in the reverse direction (REV).

FIG. 2A and FIG. 2B illustrate a problem solved by the present teachings. Teachings according to the present disclosure aim at reducing error in the coupled power by (substantially) reducing, stabilizing, or otherwise eliminating the undesired signal leaks into the CPL_{OUT} port. The present inventors have realized that a cause of presence and/or variation of the undesired signal leaks into the CPL_{OUT} port may be a variation (e.g., degradation, drop, lowering) in directivity of the power amplifier module (100) with respect to temperature. In particular, variation in performance of the power amplifier, PA, over temperature, including variation of the gain and/or impedance of the power amplifier, PA, over temperature, may affect the directivity of the power amplifier module (100) when operating in either configuration (100a) or (100b). Accordingly, by adjusting the directivity of the power amplifier module (100), error in the coupled power can be reduced.

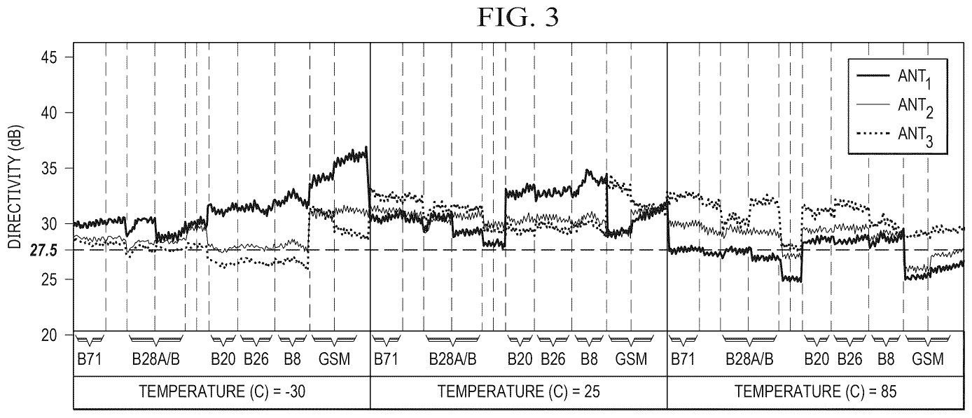

FIG. 3 shows graphs representative of measured directivity versus temperature variation of the power amplifier module (100). Directivity is measured with the power amplifier module (100) configured in the forward power detection mode and in the absence of temperature compensation according to the present teachings. Furthermore, directivity data points shown in FIG. 3 are provided for operation of the power amplifier module (100) according to different frequency bands (e.g., B71, B28, . . . , GSM, etc.) and under different loads (e.g., ANT₁, ANT₂, ANT₃). It is noted that such different frequency bands and loads may be provided through the above-described block diagram of FIG. 1B.

As shown in FIG. 3, a variation in temperature of the power amplifier module (100) may engender a variation in directivity that may be more or less pronounced depending on the frequency band of operation or of the load. For example, considering the frequency bands B20, B26 and B8 when the load is ANT₃, directivity at the temperature of −30 C (e.g., cold) is below 27.5 dB, increases to above 27.5 dB at the temperature of 25 C (e.g., room temperature), and further increases at the temperature of 85 C (e.g., hot). On the other hand, considering the same frequency bands B20, B26 and B8 when the load is ANT₁, directivity at the temperature of −30 C is above 30.0 dB, slightly increases at the temperature of 25 C, and decreases to below 30.0 dB at the temperature of 85 C. Although not shown in FIG. 3, similar results of variation of directivity with respect to temperature can be observed with the power amplifier module (100) configured in the reverse power detection mode. As previously noted, teachings according to the present disclosure aim at adjusting the directivity of the power amplifier module (100) in order to compensate for a variation of the directivity caused by a change in temperature.

It is noted that directivity of the power amplifier module (100) is different from a directivity of the directional coupler, CPL, and may be readily measured via specialized test instruments or simulated using S-parameters of the power amplifier module (100). The power amplifier module (100) can be considered as a three-port network (e.g., a three-port module) including a first port provided by the input port, RF_{IN}, a second port provided by the output port, RF_{OUT}, and third port provided by the coupled power port, CPL_{OUT}. It is noted that, as shown in FIG. 2A and FIG. 2B, the coupled power port, CPL_{OUT}, includes different paths within the power amplifier module in dependence of forward or reverse power detection mode, and therefore, different definitions of the corresponding S-parameters are provided below. The below equations represent the directivity in the forward (FWD Dir) and reverse (REV Dir) power detection modes based on the correspondingly defined S-parameters:

$$FWD Dir = \frac{{S}_{31}}{( {S}_{21} \times {S}_{32} ) - ( {S}_{22} \times {S}_{31} )}$$

where:
S₂₁ represents the forward coupling path gain between ports 1 and 2, including gain of the power amplifier, PA;
S₂₂ represents the output impedance looking into port 2;
S₃₁ represents the forward coupling path gain between ports 1 and 3, including gain of the power amplifier, PA, and forward coupling factor of the directional coupler, CPL; and
S₃₂ represents the reverse isolation between ports 3 and 2; and

$$REV Dir = \frac{{S}_{32} \times {S}_{21}}{{S}_{31}} - {S}_{22}$$

where:
S₂₁ represents the forward coupling path gain between ports 1 and 2, including gain of the power amplifier, PA;
S₂₂ represents the output impedance looking into port 2;
S₃₁ represents the forward isolation between ports 1 and 3; and
S₃₂ represents the reverse coupling factor of the directional coupler.

It should be noted that that teachings according to the present disclosure may not be limited to directivity control (e.g., temperature compensation) of the power amplifier module (100) as modeled by the above-described three-port network. According to some embodiments of the present disclosure, the temperature-controlled termination circuit, CPLTR, according to the present teachings may be used to compensate/optimize directivity of the directional coupler, CPL, per se against any temperature or impedance variation that the CPL may be exposed to. In such implementations, directivity of the CPL may be measured according to methods and techniques similar to ones described above for measuring the directivity of the power amplifier module (100). Furthermore, teachings according to the present disclosure may equally apply to directivity control (e.g., temperature compensation) of higher-level systems/modules, such as for example, a three-port module, via an embedded directional coupler (e.g., CPL) having the temperature-controlled termination circuit, CPLTR, according to the present disclosure. In such case, the embedded directional coupler may have its main-line ports (e.g., INP_{FWD}, INP_{REV}) respectively coupled to the input and output ports of the three-port module.

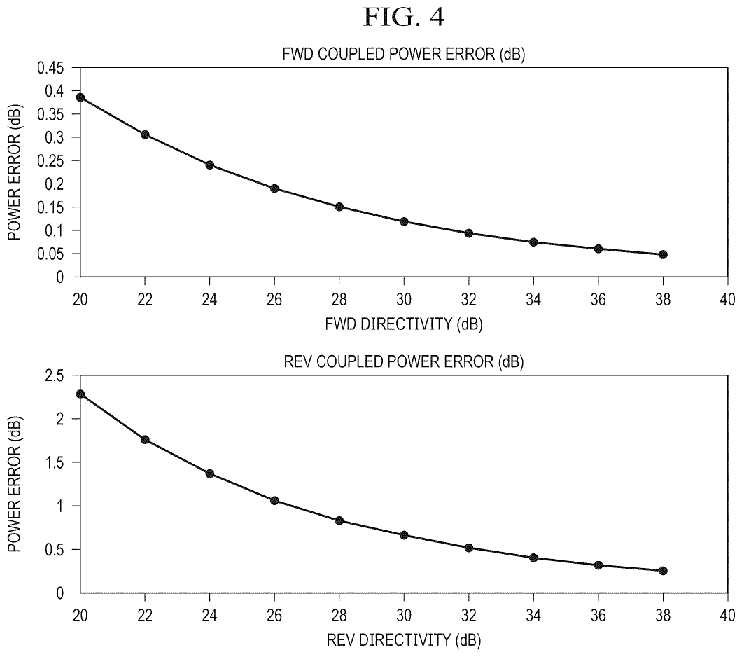

FIG. 4 shows graphs representative of relationships between directivity and coupled power error for forward (top graph) and reverse (bottom graph) power detection modes. As shown in the graphs, a strong correlation exists between directivity (labelled FWD Directivity, REV Directivity) and coupled power error (labelled Power Error). In other words, a change in directivity causes a change in an amount of error in the coupled power detected in either the forward or reverse direction. In particular, the graphs of FIG. 4 show an increase in the coupled power error for a decrease in directivity, or in other words, a degradation in the accuracy of the coupled power for a degradation in the directivity. Such graphs further validate feasibility to reduce the coupled power error by adjusting the directivity of the power amplifier module (100). It is noted that the graphs shown in FIG. 4 were obtained via simulation and validated through bench measurement. It is further noted that as shown in FIG. 4, because of a larger relative difference in the (lower) signal levels considered in the reverse power detection mode (bottom graph), coupled power error may be relatively higher in the reverse power detection mode (bottom graph) when compared to the forward power detection mode (top graph).

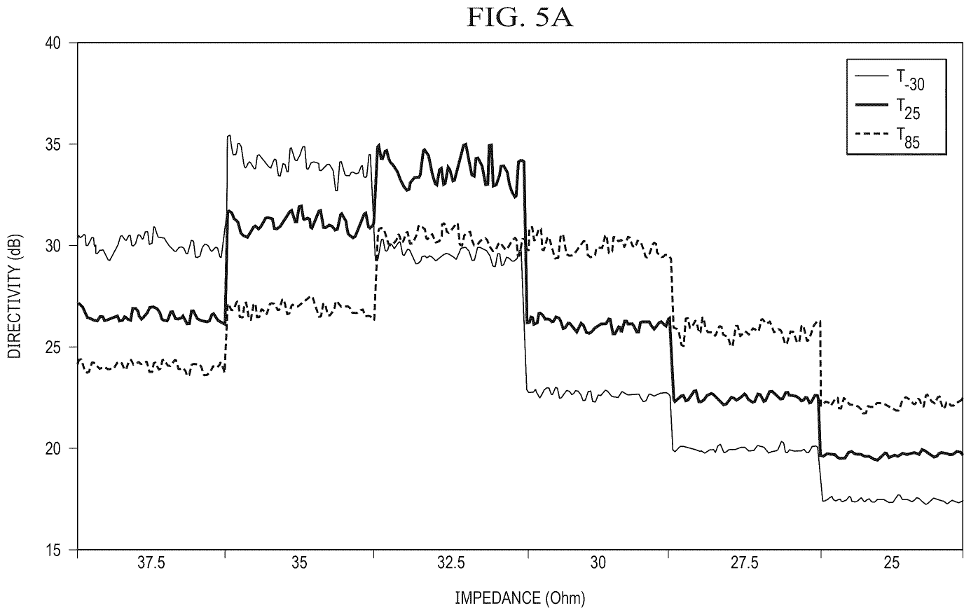

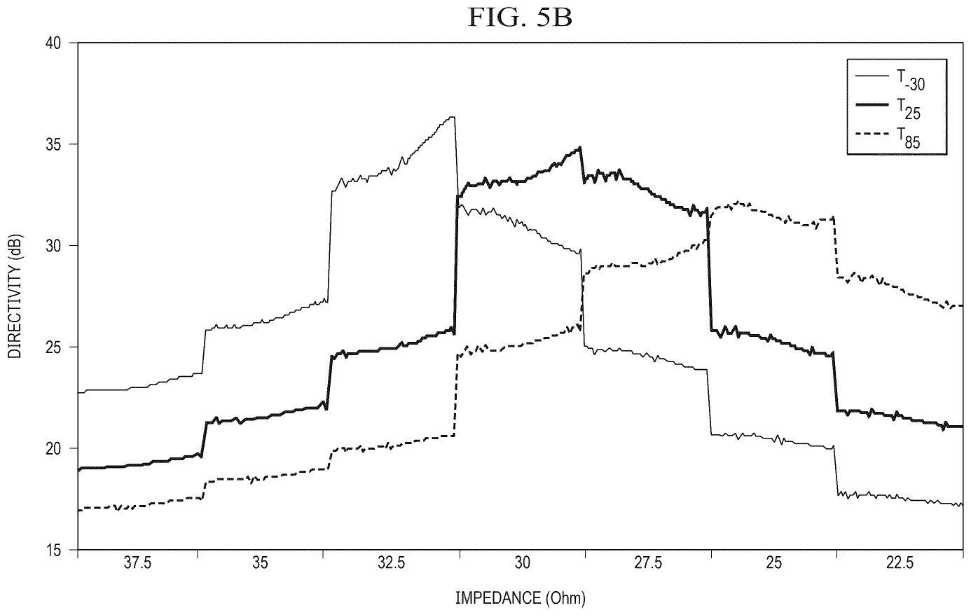

FIG. 5A and FIG. 5B show graphs representative of sensitivity of directivity of the power amplifier module (100) to varying termination resistance (labelled as Impedance) coupled to the ISO_{OUT} port over temperature (e.g. −30 C labelled as T₋₃₀, 25 C labelled as T₂₅, 85 C labelled as T₈₅) for forward (FIG. 5A) and reverse (FIG. 5B) power detection modes. These graphs show that at any given temperature (e.g., −30 C, 25 C, 85 C), the directivity of the power amplifier module (100) can be adjusted by varying the termination resistance coupled to the ISO_{OUT} port. For example, with reference to the graph shown in FIG. 5A, a substantially constant (forward) directivity of about 30 dB can be obtained across the temperatures of −30 C, 25 C and 85 C by respective termination of the ISO_{OUT} port with the termination resistances of 37.5 Ω, 35Ω and 32.5Ω. As a further example, with reference to the graph shown in FIG. 5B, a substantially constant (reverse) directivity of about 30 dB can be obtained across the temperatures of −30 C, 25 C and 85 C by respective termination of the ISO_{OUT} port with the termination resistances of 30 Ω, 27.5Ω and 25Ω.

Based on the above description with reference to FIGS. 3, 4, 5A/5B, it follows that according to the various embodiments of the present disclosure, by controllably varying the termination resistance coupled to the ISO_{OUT} port, the directivity of the power amplifier module (100) can be adjusted so to maintain a nominal directivity value across a desired temperature range, and therefore reduce or otherwise eliminate error in the coupled power provided at the CPL_{OUT} port. Because variation of the directivity versus temperature of the power amplifier module (100) under different modes of operation (e.g., frequency band, load) can be measured according to the above description with reference to FIG. 3, because a correlation between directivity and coupled power error can be established according to the above description with reference to FIG. 4, and because sensitivity (e.g., response) of the directivity to a variation in the termination resistance can be established according to the above description with reference to FIGS. 5A/5B, then an optimal control of the varying resistance coupled to the ISO_{OUT} port across a desired temperature range can be established. In other words, a coupler termination resistance having a predetermined temperature response configured to compensate variation in directivity of the power amplifier module (100) with respect to temperature can be established. As used in the present disclosure, the termination resistance refers to a resistive element (labelled as R_{NET} in the various figures) of the temperature-controlled termination circuit, CPLTR, that terminates the ISO_{OUT} port to a reference ground.

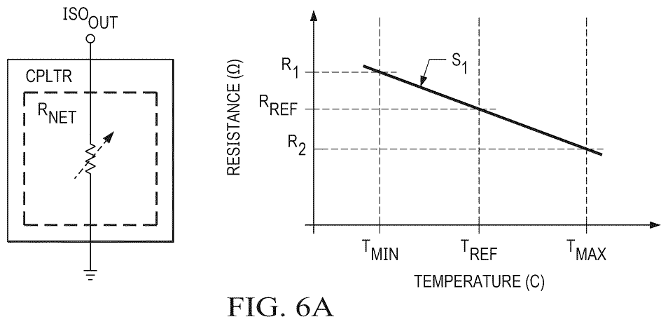

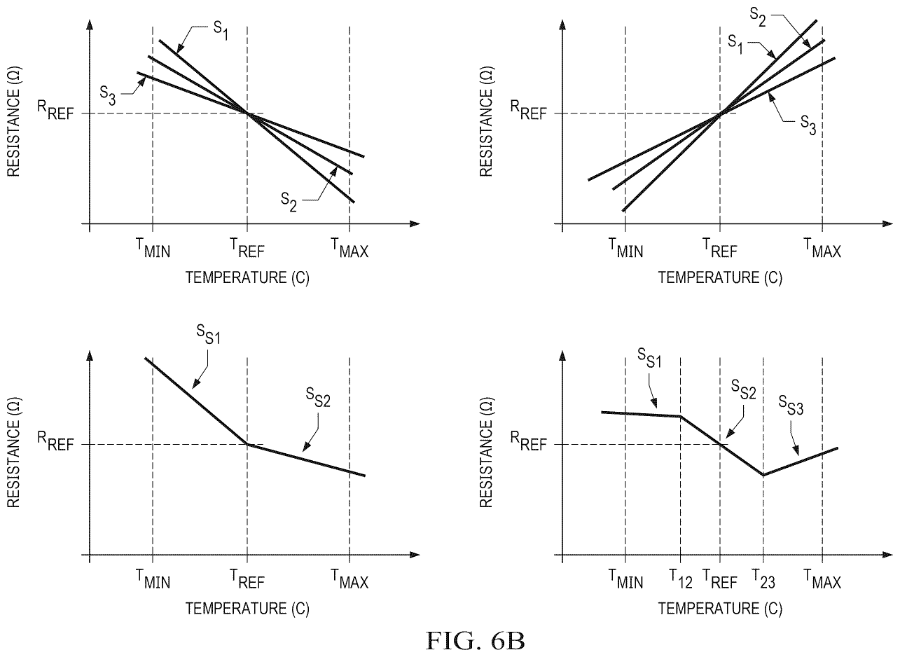

FIG. 6A shows a coupler termination resistance, R_{NET}, with an exemplary temperature response according to the present disclosure. As shown in FIG. 6A, the coupler termination resistance, R_{NET}, is part of the temperature-controlled termination circuit, CPLTR, which may further include, as shown in FIG. 1A, a termination capacitance, C_{NET}. Depending on the application, one or both of the termination resistance, R_{NET}, and the termination capacitance, C_{NET}, may be adjustable/variable/programmable/settable.

With continued reference to FIG. 6A, the exemplary temperature response may be predetermined in view of measurements according to the above description (e.g., FIGS. 3-5) and designed to compensate for temperature-dependent drifts in directivity of the power amplifier module (100). In particular, the temperature response shown in FIG. 6A may include an exemplary (negative) slope, or slope segment, that (e.g., monotonically) decreases resistance within a temperature range defined by a low temperature, T_{MIN}, a high temperature, T_{MAX}, and a nominal/reference temperature, T_{REF}. For example, at the low temperature, T_{MIN}, the resistance is R₁, at the nominal/reference temperature, T_{REF}, the resistance is R_{REF}, and at the high temperature, T_{MAX}, the resistance is R₂, with R₁>R_{REF}>R₂. Because in the exemplary case shown in FIG. 6A the predetermined temperature response is a linear function represented by a slope, then a constant temperature coefficient may be associated to such temperature response (at least) across the temperature range [T_{MIN}, T_{MAX}].

FIG. 6B shows various exemplary temperature responses of the coupler termination resistance, R_{NET}, of FIG. 6A. Teachings according to the present disclosure allow for flexibility in provision of the temperature response (e.g., profile) of the coupler termination resistance, R_{NET}, such to provide robust temperature-compensated directivity control in a power amplifier module (e.g., 100 of FIG. 1A), including in a multi-band RF transmit module (e.g., 100TX of FIG. 1B). Because directivity parameters (e.g., S-parameters) can be a function of module configuration and/or operating modes, including, for example, forward or reverse power detection modes, frequency band of operation, and/or an output load (antenna), then such flexibility can be used for provision of specific temperature profiles for specific module configurations (e.g., modes of operation).

It follows that according to an embodiment of the present disclosure, the coupler termination resistance, R_{NET}, of FIG. 6A can include a programmable (e.g., adjustable, settable, configurable, selectable) temperature response to effectively provide any one or more of the temperature responses shown in FIG. 6B, and combination thereof. These include, for example: various negative or positive slope segments (e.g., S₁, S₂, S₃) across the entirety of a temperature range of operation (e.g., [T_{MIN}, T_{MAX}]) as shown on the top region of FIG. 6B; a combination of two or more different slope segments (e.g., S_{S1}, S_{S2}) across different sub-ranges (e.g., [T_{MIN}, T_{REF}] and [T_{REF}, T_{MAX}]) of the temperature range of operation as shown on the lower left region of FIG. 6B; and/or a combination of two or more positive and negative slope segments (e.g., S_{S1}, S_{S2}, S_{S3}) across different sub-ranges (e.g., [T_{MIN}, T₁₂], [T₁₂, T₂₃] and [T₂₃, T_{MAX}]) of the temperature range of operation as shown on the lower right region of FIG. 6B. Complexity (e.g., based on number of inflection points or different slopes) of a temperature response of the coupler termination resistance, R_{NET}, according to the present disclosure may be a function of a desired resolution in compensating of a predetermined/measured directivity drift with respect to temperature. In some cases, interpolation based on few measurements for a simpler, yet efficient, temperature response (e.g., single slope) may be sufficient.

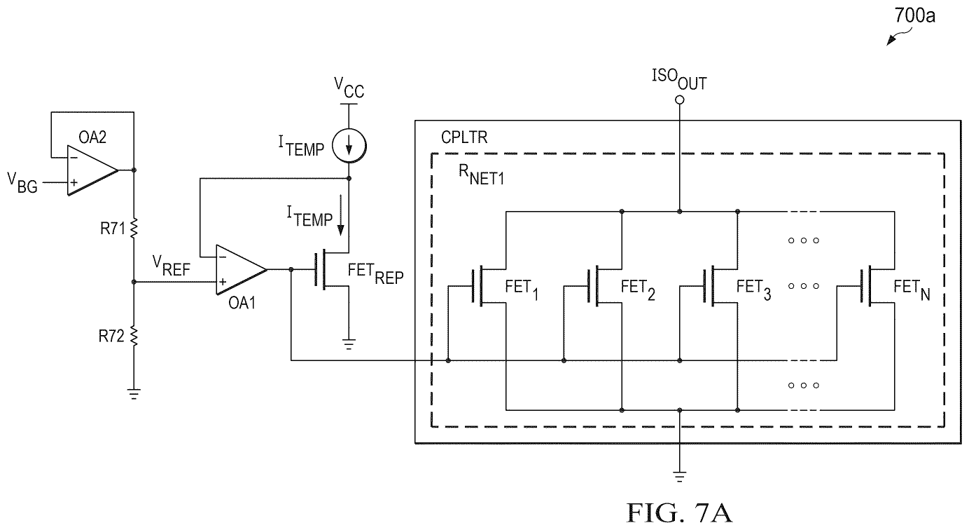

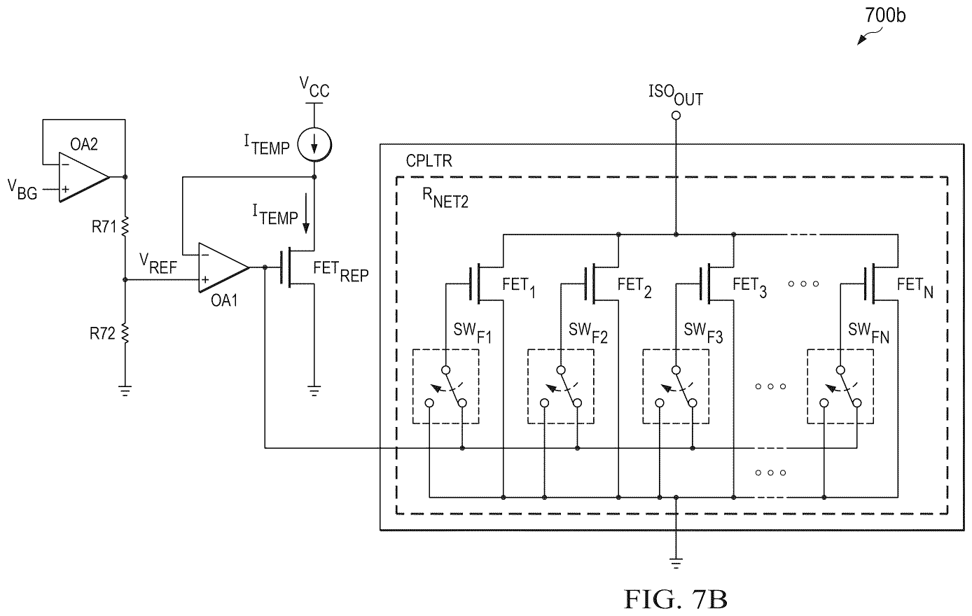

FIG. 7A shows a simplified circuit implementation (700a, including R_{NET1}) according to various embodiments of the present disclosure of the coupler termination resistance, R_{NET}, of FIG. 6A, including a basic resistance unit element provided by a FET (e.g., any one of FET₁, . . . , FET_{N}). As shown in FIG. 7A, the coupler termination resistance, R_{NET1}, may be provided by one or more FETs (e.g., FET₁, . . . , FET_{N}, N≥1) whose gate voltages are provided by an output of a first operational amplifier, OA1. Drains and sources of the FETs (e.g., FET₁, . . . , FET_{N}) are respectively connected to the ISO_{OUT} port and a reference ground. According to an embodiment of the present disclosure, each of the FETs (e.g., FET₁, . . . , FET_{N}) may operate in the triode region and therefore behave like a voltage-controlled resistance, the control voltage being a respective gate voltage (e.g., gate-to-source voltage, V_{GS}) and the resistance a respective ON resistance (e.g., R_{ON}). In some embodiments, the DC voltage on RF ports of a power amplifier module (e.g., ports RF_{IN}, RF_{OUT} of FIG. 1A) may be equal to zero volts (i.e., no DC voltage at the RF ports), and therefore the DC voltage at the ISO_{OUT} port and respective drain-to-source voltages (V_{DS}) of the FETs (e.g., FET₁, . . . , FET_{N}) may also be equal to zero volts, such as to provide operation of the FETs (e.g., FET₁, . . . , FET_{N}) in their respective triode regions.

With continued reference to FIG. 7A, a bandgap voltage reference, V_{BG}, is used to generate a stable reference voltage, V_{REF}, provided to a noninverting (positive) input of the first operational amplifier, OA1. As shown in FIG. 7A, a second operational amplifier, OA2, configured as a voltage buffer, feeds a buffered version of the bandgap voltage reference, V_{BG}, to a resistive ladder (R71, R72) coupled at the output of the second operational amplifier, thereby generating the reference voltage, V_{REF}, as a reduced (e.g., divided down) version of the bandgap voltage reference, V_{BG}, at a node (e.g., V_{REF}) connecting the two resistors R71 and R72 of the resistive ladder (R71, R72) and further connected to the noninverting input of the first operational amplifier, OA1. Because the reference voltage, V_{REF}, is directly generated from the bandgap voltage reference, V_{BG}, it can be considered as having the same properties as the bandgap voltage reference, V_{BG}, including an essentially constant voltage level that does not fluctuate/vary with respect to temperature.

With further reference to FIG. 7A, the output of the first operational amplifier, OA1, is connected to a gate of a reference FET, FET_{REP}, whose source is connected to the reference ground and drain to the inverting (e.g., negative) input of the first operational amplifier, OA1. Furthermore, a current source, I_{TEMP}, powered by a supply voltage, V_{CC}, is connected (e.g., coupled) to the drain of the reference FET, FET_{REP}, for sourcing of a current, I_{TEMP}, through the FET_{REP}. Accordingly, the connection between the first operational amplifier, OA1, and the reference FET, FET_{REP}, establishes a feedback loop that controls the gate voltage to the reference FET, FET_{REP}, so to maintain the drain voltage to the reference FET, FET_{REP}, equal to the reference voltage, V_{REF}. In other words, the feedback loop (OA1, FET_{REP}) controls the gate voltage to the reference FET, FET_{REP}, so to maintain the drain-to-source voltage of the reference FET, FET_{REP}, constant and equal to the reference voltage, V_{REF}.

According to an embodiment of the present disclosure, the resistors R71 and R72 of the resistive ladder (R71, R72) are selected to produce a voltage level of the reference voltage, V_{REF}, that is equal to about 20 mV (e.g., +/−20%), so that the drain-to-source voltage of the reference FET, FET_{REP}, is close (e.g., about equal) to the drain-to-source voltage of the FETs (e.g., FET₁, . . . , FET_{N}). Accordingly, by selecting the reference FET, FET_{REP}, as a replica of the FETs (e.g., FET₁, . . . , FET_{N}) having the same (or ratiometrically scaled) I-V characteristics, the ON resistance of each of the FETs (e.g., FET₁, . . . , FET_{N}) tracks the ON resistance of the reference FET (FET_{REP}, also operating in the triode region) as a function of the (gate) voltage provided at the output of the first operational amplifier, OA1, and controlled through the feedback loop (OA1, FET_{REP}).

With continued reference to FIG. 7A, because the reference FET, FET_{REP}, operates in the triode region, its drain-to-source voltage is equal to the product of its ON resistance (e.g., R_{ON}) and the current, I_{TEMP}, conducted between its drain and source. In other words, for the reference FET, FET_{REP}, the following equation holds: R_{ON}*I_{TEMP} V_{REF}. Accordingly, for a change in the current, I_{TEMP}, the feedback loop (OA1, FET_{REP}) controls the gate voltage to provide a corresponding change of the ON resistance of the reference FET, FET_{REP}, and therefore of the ON resistance of each of the FETs (e.g., FET₁, . . . , FET_{N}), to hold the equation true. For example, if the current, I_{TEMP}, increases, the ON resistance of the reference FET, FET_{REP}, and therefore the ON resistance of each of the FETs (e.g., FET₁, . . . , FET_{N}), is controlled to decrease. On the other hand, if the current, I_{TEMP}, decreases, the ON resistance of the reference FET, FET_{REP}, and therefore the ON resistance of each of the FETs (e.g., FET₁, . . . , FET_{N}), is controlled to increase.

According to an embodiment of the present disclosure, the current source, I_{TEMP}, shown in FIG. 7A is configured to generate/source a current, I_{TEMP}, that varies with temperature to cause a temperature dependent variation of the ON resistance of the FETs (e.g., FET₁, . . . , FET_{N}) according to a desired (e.g., the predetermined) temperature response. In other words, the current (e.g., I_{TEMP}) generated by the current, I_{TEMP}, is configured to vary with temperature according to a (current) temperature response/profile that establishes the above-described (e.g., with reference to FIGS. 6A/6B) predetermined temperature response of the coupler termination resistance, R_{NET1}.

With continued reference to FIG. 7A, according to an exemplary embodiment of the present disclosure, the current source, I_{TEMP}, may include a temperature profile provided by a proportional to absolute temperature (PTAT) profile. According to another exemplary embodiment of the present disclosure, the current source, I_{TEMP}, may include a temperature profile provided by a complementary to absolute temperature (CTAT) profile. According to yet another exemplary embodiment of the present disclosure, the current source, I_{TEMP}, may include a temperature profile provided by any one or more of a proportional to absolute temperature (PTAT) profile, and/or a complementary to absolute temperature (CTAT) profile. The temperature profile may further include a zero-proportionality to absolute temperature (ZTAT) profile. A combination of such temperature profiles may allow provision of different predetermined temperature responses of the coupler termination resistance, R_{NET1}, with one or more slope segments as shown in the above-described FIG. 6B. In some embodiments, the current source, I_{TEMP}, may include a programmable temperature profile over a desired temperature range of operation, thereby allowing for programmatical invoking of different temperature profiles for use in different modes of operation (e.g., frequency band, load, forward/reverse power detection) of the power amplifier module (e.g., 100 of FIG. 1A). It is noted that design and implementation techniques for the current source, I_{TEMP}, via temperature profiles (i.e., PTAT, CTAT, ZTAT) are outside the scope of the present disclosure. An exemplary description of current sources implemented via such temperature profiles (i.e., PTAT, CTAT, ZTAT) can be found in U.S. patent application Ser. No. 15/659,389, filed on Jul. 25, 2017, the disclosure of which is incorporated herein by reference in its entirety.

The coupler termination resistance, R_{NET1}, shown in FIG. 7A may include one or more FETs (e.g., FET₁, . . . , FET_{N}, N≥1) for provision of an effective resistance that is a parallel combination of the resistances (e.g., ON resistance) of the FETs. Because all of the gates of the FETs (e.g., FET₁, . . . , FET_{N}, N≥1) are (directly) connected to the output of the first operational amplifier, OA1, all respective resistances of the FETs participate in the provision of the effective resistance. According to an embodiment of the present disclosure, the FETs (e.g., FET₁, . . . , FET_{N}, N≥1) may include a same device type (e.g., same I-V characteristics) so that the effective resistance is based on a parallel combination of same value resistances. According to an embodiment of the present disclosure, the FETs (e.g., FET₁, . . . , FET_{N}, N≥1) may include a same device type (e.g., same I-V characteristics) but with different device sizes (e.g., width vs. length) so that the effective resistance is based on a parallel combination of ratiometrically related resistances. On the other hand, in some embodiments, the FETs (e.g., FET₁, . . . , FET_{N}, N≥1) may include different device types so that the effective resistance is based on a parallel combination of different value resistances so to provide a desired overall temperature response of the effective resistance.

According to an embodiment of the present disclosure, and as shown in the simplified circuit implementation (700b, including R_{NET2}) of FIG. 7B, participation of any one or more of the FETs (e.g., FET₁, . . . , FET_{N}, N≥1) in provision of an effective resistance can be made selective so to allow selective control of the effective resistance. It is noted that because the coupler termination resistance is temperature-dependent according to a predetermined temperature response, the expression “effective resistance” as used herein may refer to a resistance at a given (fixed and arbitrary) temperature. The effective resistance when given at a reference (e.g., room temperature, 25 C), may be referred to as “reference resistance”, and denoted in the various figures as “R_{REF}”.

With further reference to FIG. 7B, a coupler termination resistance, R_{NET2}, that includes one or more switches (e.g., SW_{F1}, . . . , SW_{FN}) is presented, each switch coupled to a respective FET of the one or more FETs (e.g., FET₁, . . . , FET_{N}, N≥1). According to an embodiment of the present disclosure, each switch (e.g., SW_{F1}, . . . , SW_{FN}) may selectively couple (or decouple) the gate of the respective FET (e.g., FET₁, . . . , FET_{N}, N≥1) to (or from) the output of the first operational amplifier, OA1, to selectively include (or exclude) a respective ON resistance of the FET in (or out) of the effective resistance provided by the coupler termination resistance, R_{NET2}. According to an exemplary embodiment of the present disclosure, each switch (e.g., SW_{F1}, . . . , SW_{FN}) may include one pole connected to the gate of the respective FET (e.g., FET₁, . . . , FET_{N}, N≥1) and a first throw connected to the output of the first operational amplifier, OA1. According to another exemplary embodiment of the present disclosure, each switch (e.g., SW_{F1}, . . . , SW_{FN}) may include a second throw connected to a reference voltage, such as, for example, the reference ground. Inclusion of a FET (e.g., FET₁, . . . , FET_{N}, N≥1) in the effective resistance may be provided by controlling the respective switch (e.g., SW_{F1}, . . . , SW_{FN}) to couple/connect the respective pole to the first throw, and exclusion of the FET from the effective resistance may be provided by controlling the respective switch to couple/connect the respective pole to the second throw.

The coupler termination resistance, R_{NET2}, of FIG. 7B may be considered as a programmable coupler termination resistance that may be configured to selectively provide a predetermined effective resistance at a specific temperature (e.g., room temperature) and further controlled to vary with temperature via the feedback loop (OA1, FET) in combination with the current source, I_{TEMP}. Increased flexibility in implementation of a coupler termination resistance can thereby be provided for optimal temperature-compensated directivity control across various modes of operation (e.g., frequency band, load, forward/reverse power detection) of the power amplifier module (e.g., 100 of FIG. 1A). It is noted that other arrangements of the switches for provision of a programmable coupler termination resistance can be envisioned.

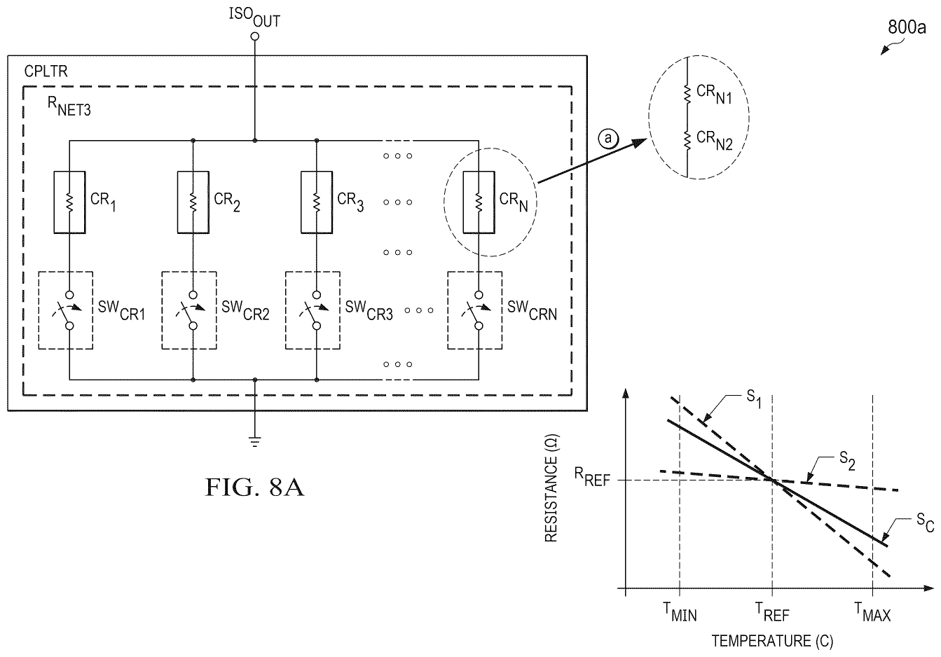

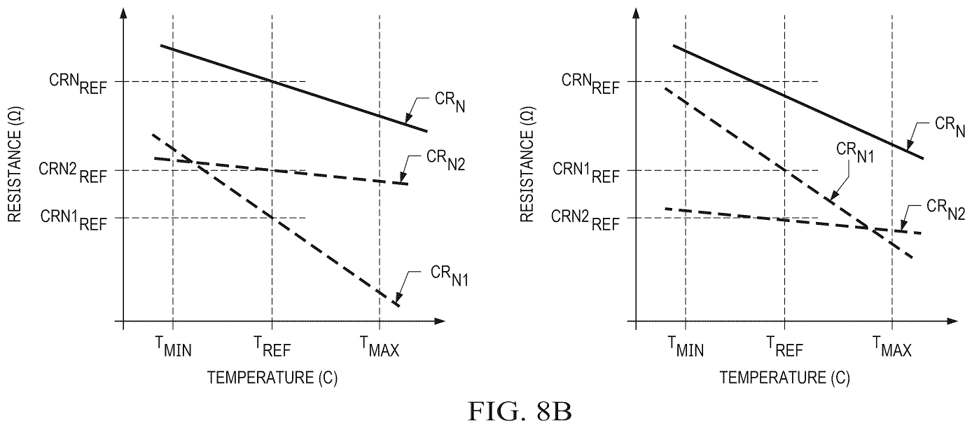

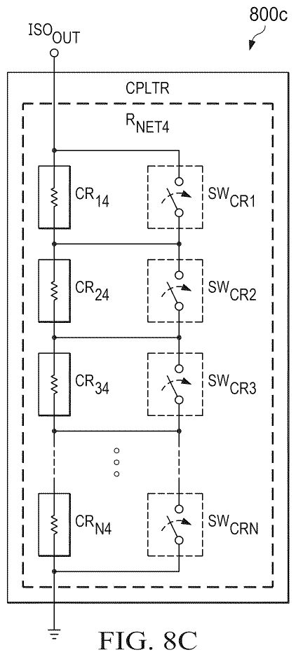

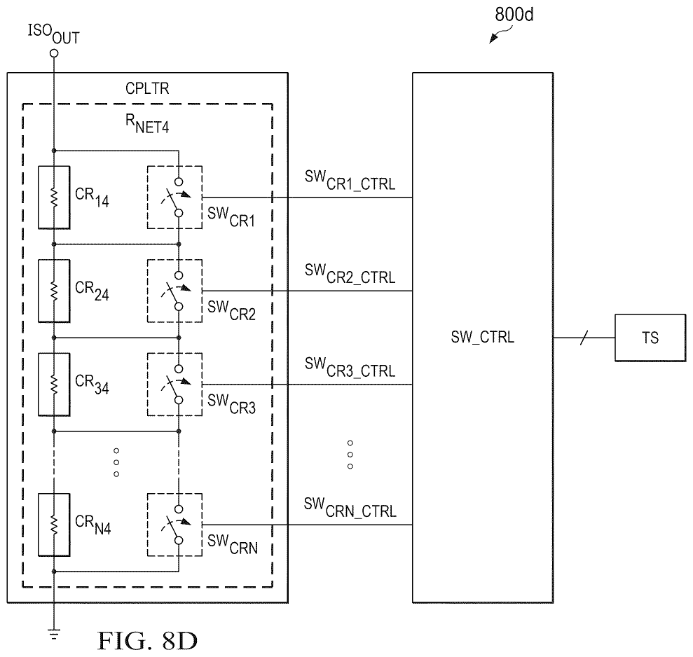

FIG. 8A shows a simplified circuit implementation (800a, R_{NET3}) according to an embodiment of the present disclosure of the coupler termination resistance, R_{NET}, of FIG. 6A, including a basic resistance unit element provided by a composite resistor (e.g., any one of CR₁, . . . , CR_{N}). The composite resistor (e.g., any one of CR₁, . . . , CR_{N}) according to the present disclosure includes a combination of resistors with different inherent/characteristic temperature coefficients. For example, as shown in FIG. 8A, the composite resistor, CR_{N}, may include two series connected resistors, CR_{N1} and CR_{N2}, each with a different temperature coefficient, such as, for example, an N-type polysilicon resistor and a P-type polysilicon resistor. Accordingly, as shown in FIG. 8A, each of the resistors, CR_{N1} and CR_{N2}, includes a temperature response represented by a different slope (e.g., S₁ and S₂, shown for a same reference resistance, R_{REF}) over a temperature range of operation (e.g., [T_{MIN}, T_{MAX}]).

Accordingly, as shown in FIG. 8A, a temperature response of the composite resistor, CR_{N}, may be represented by a slope (e.g., Sc, shown for the same reference resistance, R_{REF}) provided/obtained by (ratiometrically) combining the respective slopes (e.g., S₁ and S₂) of the resistors CR_{N1} and CR_{N2}. As shown in FIG. 8B, by changing a ratio of the effective/reference resistances of the resistors CR_{N1} and CR_{N2} while maintaining a constant/fixed effective/reference resistance, the slope, Sc, of the composite resistor, CR_{N}, can be changed.

FIG. 8B shows two exemplary realizations of the basic resistance unit element (e.g., composite resistor CR_{N}, applicable to any one of the composite resistors CR₁, . . . , CR_{N} of FIG. 8A). The first realization shown in the left region of FIG. 8B, implements a reference resistance, CRN_{REF}, of the composite resistor CR_{N}, via a reference resistance, CRN2_{REF}, of the resistor CR_{N2}, that is greater than a reference resistance, CRN1_{REF}, of the resistor CR_{N1}. On the other hand, the second realization shown in the right region of FIG. 8B, implements the same reference resistance, CRN_{REF}, of the composite resistor CR_{N}, via a reference resistance, CRN1_{REF}, of the resistor CR_{N1}, that is greater than a reference resistance, CRN2_{REF}, of the resistor CR_{N2}. Accordingly, and as shown in the FIG. 8B, because the temperature response of the resistor CR_{N1} has a greater slope than that of the resistor CR_{N2}, and because a ratio between the reference resistance, CRN1_{REF}, to the reference resistance, CRN2_{REF}, is greater in the second realization, then the (combined) temperature response of the composite resistor CR_{N} according to the second realization includes a greater slope. Accordingly, each of the composite resistors (e.g., CR₁, . . . , CR_{N} of FIG. 8A) used in the coupler termination resistance, R_{NET3}, of FIG. 8A can be realized with a temperature response having a (desired) predetermined slope.

With reference back to FIG. 8A, a first terminal of each composite resistor (e.g., CR₁, . . . , CR_{N}) of the coupler termination resistance, R_{NET3}, may be connected to the isolation port, ISO_{OUT}. Accordingly, for a case where a plurality of composite resistors is present, the respective first terminals are tied to one another. Furthermore, the coupler termination resistance, R_{NET3}, may include one or more switches (e.g., SW_{CR1}, . . . , SW_{CRN}), each switch coupled (in series) to a second terminal of a respective composite resistor (e.g., CR₁, . . . , CR_{N}). According to an embodiment of the present disclosure, each switch (e.g., SW_{CR1}, . . . , SW_{CRN}) may selectively couple (or decouple) the second terminal of the respective composite resistor (e.g., CR₁, . . . , CR_{N}) to (or from) the reference ground, to selectively include (or exclude) a respective resistance of the composite resistor in (or out) of the coupler termination resistance, R_{NET3}. According to an exemplary embodiment of the present disclosure, each switch (e.g., SW_{CR1}, . . . , SW_{CRN}) may include a single-pole single-throw switch.

Similarly to the configurations described above with reference to FIG. 7B, the one or more switches (e.g., SW_{CR1}, . . . , SW_{CRN}) in combination with the one or more composite resistors (e.g., CR₁, . . . , CR_{N}), may allow programmability of the coupler termination resistance, R_{NET3}, of FIG. 8A so to selectively provide a predetermined effective/reference resistance at a specific temperature (e.g., room temperature) and further configured to vary with temperature according to a predetermined temperature response. Increased flexibility in implementation of a coupler termination resistance can thereby be provided for optimal temperature-compensated directivity control across various modes of operation (e.g., frequency band, load, forward/reverse power detection) of the power amplifier module (e.g., 100 of FIG. 1A).

FIG. 8C shows a simplified circuit implementation (800c, R_{NET4}) according to an embodiment of the present disclosure of the coupler termination resistance, R_{NET}, of FIG. 6A, including a basic resistance unit element provided by a composite resistor (e.g., any one of CR₁₄, . . . , CR_{N4}). The implementation shown in FIG. 8C can be considered as a variant of the implementation (800a, R_{NET3}) described above with reference to FIGS. 8A/8B, while providing similar benefits. In particular, the one or more resistors (e.g., composite resistors CR₁₄, . . . , CR_{N4}) of the coupler termination resistance, R_{NET4}, are arranged in series connection between the isolation port, ISO_{OUT}, and the reference ground. On the other hand, each of the one or more switches (e.g., SW_{CR1}, . . . , SW_{CRN}) is connected in parallel with a respective resistor (e.g., composite resistors CR₁₄, . . . , CR_{N4}). Accordingly, closing a switch of the one or more switches (e.g., SW_{CR1}, . . . , SW_{CRN}) will short the respective resistor (e.g., composite resistors CR₁₄, . . . , CR_{N4}). Shorting of any one or more of the resistors (e.g., composite resistors CR₁₄, . . . , CR_{N4}) may be in view of a mode of operation of the power amplifier module (e.g., 100 of FIG. 1A) for providing a predetermined (and corresponding) temperature response of the coupler termination resistance.

In an alternate embodiment of the present disclosure, the one or more resistors (e.g., CR₁₄, . . . , CR_{N4}) of FIG. 8C may not each be a composite resistor, rather, the one or more resistors (e.g., CR₁₄, . . . , CR_{N4}) may include resistors with different inherent/characteristic temperature coefficients, while the one or more switches (e.g., SW_{CR1}, . . . , SW_{CRN}) may realize a composite resistor by selectively including in the coupler termination resistance, R_{NET4}, a combination of series connected resistors of the one or more with (e.g., CR₁₄, . . . , CR_{N4}) having at least two different inherent/characteristic temperature coefficients. In other words, realization of the composite resistor according to the description above with reference to FIG. 8B may be provided on the fly. It is noted that the various embodiments described above with reference to FIGS. 8A/8C may be combined.

It is noted that a number, N, of composite resistors (e.g., CR₁, . . . , CR_{N} of FIG. 8A or CR₁₄, . . . , CR_{N4} of FIG. 8C) may be dependent on various factors, including design goals and expected performances. Furthermore, any number of such composite resistors (e.g., CR₁, . . . , CR_{N} of FIG. 8A or CR₁₄, . . . , CR_{N4} of FIG. 8C), including none, some, or all, may be coupled to a respective switch (e.g., SW_{CR1}, . . . , SW_{CRN}). Furthermore, more complex temperature responses may be envisioned by including (e.g., switching in) during a same mode of operation a plurality of the composite resistors (e.g., CR₁, . . . , CR_{N} of FIG. 8A or CR₁₄, . . . , CR_{N4} of FIG. 8C). In some embodiments according to the present disclosure, the including (e.g., switching in) may be provided dynamically during the same mode of operation and synchronous to different events, including, for example, temperature-based events, such as, for example, (real-time) detected high and/or low temperatures as shown in the exemplary embodiment represented by FIG. 8D.

FIG. 8D shows a simplified block diagram of a coupler termination resistance with temperature-based switch control (800d). In such implementation, a temperature sensor, TS, is used to sense (e.g., detect) a temperature (either local or remote) and provide a measurement/signal indicative of the sensed temperature to a switch control block, SW_CTRL, which in turn controls ON/OFF states of the switches (e.g., SW_{CR1}, . . . , SW_{CRN}) of the composite resistors (e.g., CR₁₄, . . . , CR_{N4}) of the (exemplary) coupler termination resistance, R_{NET4}. The temperature sensor, TS, may include a built-in analog-to-digital converter (ADC, not shown in FIG. 8D) that converts an analog signal to a digital signal (e.g., word) that is read by the switch control block, SW_CTRL. The switch control block, SW_CTRL, may include control logic and/or algorithms that map the digital signal (i.e., sensed temperature) to switch control signals, SW_{CR1_CTRL}, . . . , SW_{CRN_CTRL}, that control respective ON/OFF states of the switches, SW_{CR1}, . . . , SW_{CRN}. Functionality of the switch control block, SW_CTRL, can be implemented, for example, via a memory-based lookup table (LUT), a programmable logic gate structure (e.g., FPGA or other), or a microprocessor/controller.

According to an embodiment of the present disclosure, operation of the coupler termination resistance with temperature-based switch control (800d) of FIG. 8D may be based on real-time monitoring of the temperature and adjusting of the effective coupler termination resistance. According to another embodiment of the present disclosure, operation of the coupler termination resistance with temperature-based switch control (800d) may be based on monitoring of the temperature and adjusting of the effective coupler termination resistance at discrete times or time intervals as part of a calibration routine. Such calibration routine may, for example, seek to calibrate (e.g., optimize) directivity based on current temperature. It is noted that the temperature-based switch control according to the present teachings can be implemented with the coupler termination resistance, R_{NET4}, as shown in FIG. 8D, or with the coupler termination resistance, R_{NET3}, described above with reference to FIG. 8A.

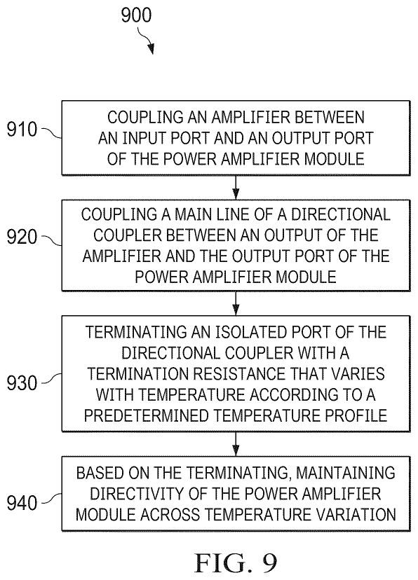

FIG. 9 is a process chart (900) showing various steps of a method according to the present disclosure for maintaining directivity of a power amplifier module. As shown in FIG. 9, such steps include: coupling an amplifier between an input port and an output port of the power amplifier module, according to step (910); coupling a main line of a directional coupler between an output of the amplifier and the output port of the power amplifier module, according to step (920); terminating an isolated port of the directional coupler with a termination resistance that varies with temperature according to a predetermined temperature profile, according to step (930); and based on the terminating, maintaining directivity of the power amplifier module across temperature variations, according to step (940).

The term “MOSFET”, as used in this disclosure, includes any field effect transistor (FET) having an insulated gate whose voltage or charge level determines the conductivity of the transistor, and encompasses insulated gates having a metal or metal-like, insulator, and/or semiconductor structure. The terms “metal” or “metal-like” include at least one electrically conductive material (such as aluminum, copper, or other metal, or highly doped polysilicon, graphene, or other electrical conductor), “insulator” includes at least one insulating material (such as silicon oxide or other dielectric material), and “semiconductor” includes at least one semiconductor material.

As used in this disclosure, the term “radio frequency” (RF) refers to a rate of oscillation in the range of about 3 kHz to about 300 GHz. This term also includes the frequencies used in wireless communication systems. An RF frequency may be the frequency of an electromagnetic wave or of an alternating voltage or current in a circuit.

Various embodiments of the invention can be implemented to meet a wide variety of specifications. Unless otherwise noted above, selection of suitable component values is a matter of design choice. Various embodiments of the invention may be implemented in any suitable integrated circuit (IC) technology (including but not limited to MOSFET structures), or in hybrid or discrete circuit forms. Integrated circuit embodiments may be fabricated using any suitable substrates and processes, including but not limited to standard bulk silicon, high-resistivity bulk CMOS, silicon-on-insulator (SOI), and silicon-on-sapphire (SOS). Unless otherwise noted above, embodiments of the invention may be implemented in other transistor technologies, such as bipolar junction transistors (BJTs), BiCMOS, LDMOS, BCD, GaAs HBT, GaN HEMT, GaAs pHEMT, MESFET, InP HBT, InP HEMT, FinFET, GAAFET, and SiC-based device technologies, using 2-D, 2.5-D, and 3-D structures. However, embodiments of the invention are particularly useful when fabricated using an SOI or SOS based process, or when fabricated with processes having similar characteristics. Fabrication in CMOS using SOI or SOS processes enables circuits with low power consumption, the ability to withstand high power signals during operation due to FET stacking, good linearity, and high frequency operation (i.e., radio frequencies up to and exceeding 300 GHz). Monolithic IC implementation is particularly useful since parasitic capacitances generally can be kept low (or at a minimum, kept uniform across all units, permitting them to be compensated) by careful design.

Voltage levels may be adjusted, and/or voltage and/or logic signal polarities reversed, depending on a particular specification and/or implementing technology (e.g., NMOS, PMOS, or CMOS, and enhancement mode or depletion mode transistor devices). Component voltage, current, and power handling capabilities may be adapted as needed, for example, by adjusting device sizes, serially “stacking” components (particularly FETs) to withstand greater voltages, and/or using multiple components in parallel to handle greater currents. Additional circuit components may be added to enhance the capabilities of the disclosed circuits and/or to provide additional functionality without significantly altering the functionality of the disclosed circuits.

A number of embodiments of the invention have been described. It is to be understood that various modifications may be made without departing from the spirit and scope of the invention. For example, some of the steps described above may be order independent, and thus can be performed in an order different from that described. Further, some of the steps described above may be optional. Various activities described with respect to the methods identified above can be executed in repetitive, serial, and/or parallel fashion.

It is to be understood that the foregoing description is intended to illustrate and not to limit the scope of the invention, which is defined by the scope of the following claims, and that other embodiments are within the scope of the claims. In particular, the scope of the invention includes any and all feasible combinations of one or more of the processes, machines, manufactures, or compositions of matter set forth in the claims below. (Note that the parenthetical labels for claim elements are for ease of referring to such elements, and do not in themselves indicate a particular required ordering or enumeration of elements; further, such labels may be reused in dependent claims as references to additional elements without being regarded as starting a conflicting labeling sequence).

1. A power amplifier module, comprising:
an amplifier configured to amplify a signal provided at an input port of the power amplifier module;
a directional coupler having a main line coupled between an output of the amplifier and an output port of the power amplifier module; and
a termination circuit coupled to an isolated port of the directional coupler, the termination circuit comprising a termination resistance that varies with temperature according to a temperature profile configured to maintain directivity of the power amplifier module across temperature variations.

2. The power amplifier module of claim 1, wherein:
the termination resistance is programmable to provide a plurality of termination resistances that vary according to a respective plurality of temperature profiles configured to maintain directivity of the power amplifier module across temperature variations for a respective plurality of modes of operation of the power amplifier module.

3. The power amplifier module of claim 2, wherein:
the plurality of modes of operation includes a frequency band of operation, a load coupled to the output port, or a coupler power detection mode.

4. The power amplifier module of claim 3, wherein:
the coupler power detection mode includes a forward power detection mode and a reverse power detection mode, and
the termination resistance is further configured to reduce coupled power errors in the coupler power detection mode.

5. The power amplifier module of claim 1, wherein:
the temperature profile is predetermined and based on measured and/or simulated data representing variation of the directivity of the power amplifier module with temperature.

6. The power amplifier module of claim 5, wherein:
the temperature profile is further based on measured and/or simulated correlation data between the directivity of the power amplifier module and the termination resistance coupled to the isolated port of the directional coupler.

7. The power amplifier module of claim 1, wherein:
the termination circuit comprises one or more FETs configured to operate in the triode region, the termination resistance provided by ON resistances of the one or more FETs.

8. The power amplifier module of claim 7, wherein:
the termination circuit includes a feedback loop that controls gate voltages to the one or more FETs to vary the ON resistances with temperature according to the temperature profile.

9. The power amplifier module of claim 8, wherein:
the feedback loop controls the gate voltages based on a temperature-dependent current conducted between a drain and a source of a reference FET and a temperature-stable voltage coupled to the drain of the reference FET.

10. The power amplifier module of claim 9, wherein:
the feedback loop controls a voltage to a gate of the reference FET to maintain the temperature-stable voltage constant over variation of the temperature-dependent current.

11. The power amplifier module of claim 9, wherein
the feedback loop includes an operational amplifier having:
a first input coupled to the temperature-stable voltage;
a second input coupled to the drain of the reference FET; and
an output coupled to the gate of the reference FET and to gates of the one or more FETs.

12. The power amplifier module of claim 11, wherein
the output of the operational amplifier is selectively coupled to the gates of the one or more FETs through respective one or more switches.

13. The power amplifier module of claim 9, wherein:
the termination circuit includes a current source configured to generate the temperature-dependent current, and
the current source includes a current temperature profile according to, or based on, one or more of: a proportional to absolute temperature (PTAT) profile, or a complementary to absolute temperature (CTAT) profile.

14. The power amplifier module of claim 13, wherein:
the current temperature profile is further based on a zero-proportionality to absolute temperature (ZTAT) profile.

15. The power amplifier module of claim 13, wherein:
the current source is programmable to provide a plurality of current temperature profiles.

16. The power amplifier module of claim 1, wherein:
the termination circuit comprises one or more composite resistors for provision of the termination resistance, and
each composite resistor of the one or more composite resistors comprises a combination of at least two resistors with different characteristic temperature coefficients.

17. The power amplifier module of claim 16, wherein:
the at least two resistors include an N-type polysilicon resistor and a P-type polysilicon resistor.

18. The power amplifier module of claim 16, wherein:
a ratio of resistances of the at least two resistors is selected to control a composite temperature coefficient of the each composite resistor.

19. The power amplifier module of claim 16, wherein:
the at least two resistors are arranged in series connection.

20. The power amplifier module of claim 16, wherein:
the termination circuit further comprises one or more switches, and
each switch of the one or more switches is coupled to a respective composite resistor of the one or more composite resistors.

21. The power amplifier module of claim 20, wherein:
each switch of the one or more switches is coupled in series with the respective composite resistor.

22. The power amplifier module of claim 20, wherein:
each switch of the one or more switches is coupled in parallel with the respective composite resistor.

23.-72. (canceled)
